(19) United States
(12) Patent Application Publication
(10) Pub. No.: US 2022/0045479 A1
(43) Pub. Date: Feb. 10, 2022

(54) RESONANT RECHARGE FOR SYNCHRONOUS PULSED LASER OPERATION

(71) Applicant: SEMICONDUCTOR COMPONENTS INDUSTRIES, LLC, Phoenix, AZ (US)

(72) Inventors: John William WAGNER, Ann Arbor, MI (US); Michael N. BORZA, Beaverton, OR (US)

(73) Assignee: SEMICONDUCTOR COMPONENTS INDUSTRIES, LLC, Phoenix, AZ (US)

(21) Appl. No.: 16/949,119

(22) Filed: Oct. 14, 2020

Related U.S. Application Data
(60) Provisional application No. 63/061,941, filed on Aug. 6, 2020.

(51) Int. Cl. H01S 5/042; H01S 5/40; H01S 5/06; H01S 5/068; G01S 7/484

(52) U.S. Cl. CPC H01S 5/0428; H01S 5/4025; G01S 7/484; H01S 5/06808; H01S 5/0608

(57) ABSTRACT

Resonant recharge for synchronous pulsed laser operation. At least one example embodiment is a method of activating a laser diode, the method including: creating an oscillating voltage at a node between an inductor and a first capacitor, the oscillating voltage having a positive half-cycle and a negative half-cycle; charging a firing capacitor during a positive half-cycle of the oscillating voltage, the charging from the node and through a diode; and driving, during a negative half-cycle of the oscillating voltage, a pulse of current from the firing capacitance through a laser diode.

### CROSS-REFERENCE TO RELATED APPLICATIONS

This application claims the benefit of U.S. Provisional Application No. 63/061,941 filed Aug. 6, 2020 and titled “Resonant Recharge Synchronous Pulsed Laser Driver.” The provisional application is incorporated herein by reference as if reproduced in full below.

### BACKGROUND

Many systems use light detection and ranging (hereafter “lidar”) to implement vision-like control. Such systems include weapons systems, mobile autonomous robots, safety systems for automobiles, and semi-autonomous and autonomous driving systems. For pulsed-power laser drivers, capacitive discharge circuits employ recharge methods that generate excess heat (e.g., charging through a resistor). Such recharge methods result in high power dissipation, especially for higher pulse repetition frequencies (e.g. greater than 20 kilohertz or more). Moreover, in some cases the power dissipation limits the operating frequency.

Some laser driver circuits utilize energy stored in an inductor to drive one or more laser diodes. However, laser driver circuits which utilize inductors may have to operate at higher voltage to overcome the loop inductance of the current path through the laser diode. Moreover, increasing inductance in the loop slows the rise time of the current waveform. The slow rise times become an issue in lidar systems that employ either a Single Photon Avalanche Diode (SPAD) or a Silicon Photo-Multiplier (SiPM) as the detector. That is, the accuracy of such systems is based on using fast pulses with sharp leading edges. It follows that use of inductors as the energy source may slow the rise time of pulses, and thus lower accuracy.

### SUMMARY

One example embodiment is a method of activating a laser diode, the method comprising: creating an oscillating voltage at a node between an inductor and a first capacitor, the oscillating voltage having a positive half-cycle and a negative half-cycle; charging a firing capacitor during the positive half-cycle of the oscillating voltage, the charging from the node and through a diode; and driving, during the negative half-cycle of the oscillating voltage, a pulse of current from the firing capacitor through the laser diode.

In the example method, creating the oscillating voltage at the node may further comprise: a) coupling a first lead of the inductor to a power source; and then b) coupling the first lead of the inductor to ground; and c) repeating steps a) and b) at a resonant frequency.

In the example method, charging the firing capacitor may further comprise charging the firing capacitor in parallel with charging the first capacitor during the positive half-cycle of the oscillating voltage.

In the example method, driving the pulse of current from the firing capacitor further comprises discharging the firing capacitor through the laser diode and an electrically-controlled switch.

Another example embodiment is a driver integrated circuit for controlling activation of a laser diode, the driver integrated circuit comprising: a high-gate terminal, a low-gate terminal, a sense terminal, and a pulse-gate terminal; a resonance controller coupled to the high-gate terminal and the low-gate terminal, the resonance controller configured to assert the high-gate terminal for a first duration within a switching period, and configured to assert the low-gate terminal for a second duration within the switching period; and a firing controller coupled to the sense terminal and the pulse-gate terminal, the resonance controller configured to assert the pulse-gate terminal based on a signal sensed by way of the sense terminal.

The example driver integrated may further comprise a pulse-enable terminal. The firing controller may be coupled to the pulse-enable terminal, and the firing controller may be further configured to assert the pulse-gate terminal when the pulse-enable terminal is asserted.

The driver integrated circuit may further comprise: the signal sensed by way of the sense terminal is a signal indicative of voltage at a charge node; and wherein the firing controller asserts the pulse-gate terminal only when the signal indicative of voltage indicates a voltage on the charge node is negative.

The driver integrated circuit may further comprise: the signal sensed by way of the sense terminal is a signal indicative of current flow in an inductor-capacitor circuit; and wherein the firing controller asserts the pulse-gate terminal only when the signal indicative of current flow indicates a voltage on a charge node is negative.

The driver integrated circuit may further comprise the resonance controller coupled to the sense terminal. The resonance controller may be further configured to: measure an attribute of oscillation on the by way of the sense terminal; and control frequency of assertion of the high-gate terminal based on the attribute of oscillation.

Another example embodiment is a driver integrated circuit for controlling activation of a laser diode, the driver integrated circuit comprising: a source terminal, a switch-node terminal, a sense terminal, a ground terminal, and a pulse-gate terminal; a high-side field-effect transistor (high-side FET) defining a drain coupled to the source terminal, a source coupled to the switch-node terminal, and a gate; a low-side FET defining a drain coupled to the switch-node terminal, a source coupled to the ground terminal, and a gate; a resonance controller coupled to the gate of the high-side FET and the gate of the low-side FET, the resonance controller configured to assert the gate of the high-side FET for a first duration within a switching period, and configured to assert the gate of the low-side FET during a second duration within the switching period; and a firing controller coupled to the sense terminal and the pulse-gate terminal, the firing controller configured to sense an attribute of oscillation through the sense terminal, and assert the pulse-gate terminal based on the attribute of oscillation.

The second example driver integrated circuit may further comprise a pulse-enable terminal. The firing controller may be coupled to the pulse-enable terminal, and the firing controller may be further configured to assert the pulse-gate terminal only when the pulse-enable terminal is asserted.

The second example driver integrated may further comprise: the attribute of oscillation is a signal indicative of voltage at a charge node; and wherein the firing controller asserts the pulse-gate terminal only when the signal indicative of voltage indicates a voltage on the charge node is negative.

The second example driver integrated circuit may further comprise: the attribute of oscillation is a signal indicative of current flow in an inductor-capacitor (LC) circuit; and wherein the firing controller asserts the pulse-gate terminal only when the signal indicative of current flow indicates a voltage on a charge node is negative.

The second example driver integrated circuit may further comprise: the resonance controller coupled to the sense terminal, and the resonance controller further configured to:

sense the attribute of oscillation by way of the sense terminal; and control frequency of assertion of the gate of the high-side FET based on the attribute of oscillation.

Another example embodiment is a system for light detecting and ranging, comprising: an inductor-capacitor circuit (LC circuit) defining a first lead, a second lead, and a charge node between an inductor and a capacitor; a high-side switch defining a first lead coupled to a power supply, a second lead coupled to the first lead of the LC circuit, and a control input; a low-side switch defining a first lead coupled to the first lead of the LC circuit, a second lead coupled to the ground, and a control input; a diode defining an anode coupled to the charge node, and a cathode; a firing capacitor defining a first lead coupled to the cathode of the diode, and a second lead coupled to the to the ground; a laser diode; a pulse-control switch coupled to the firing capacitor and the laser diode, the pulse-control switch configured to couple the firing capacitor to the laser diode based on a control input; and a resonance controller coupled to the control inputs of the high-side switch, the low-side switch, and the pulse-control switch. The resonance controller may be configured to: create an oscillating voltage at the charge node by control of the high-side switch and the low-side switch, the oscillating voltage having a frequency, a positive half-cycle, and a negative half-cycle; and generate a laser pulse from the laser diode during the negative half-cycle of the oscillating voltage by making the pulse-control switch conductive.

In the example system, when the resonance controller creates the oscillating voltage at the charge node, the resonance controller may be further configured to: a) assert the control input of the high-side switch to couple the first lead of the LC circuit to a power source; and then b) assert the control input of the low-side switch to couple the first lead of the LC circuit to ground; and c) repeat steps a) and b) at the frequency.

The example system may comprise a firing controller defining a pulse-enable input, the firing controller configured to assert the control input of the pulse-control switch only during the negative half-cycle of the oscillating voltage when the pulse-enable input is asserted.

The example system may further comprise: a current sensor associated with the charge node; and the resonance controller coupled to the current sensor. The resonance controller may be further configured to: measure values indicative of current by way of the current sensor; and control the frequency of the oscillating voltage based on the values indicative of current.

In the example system, the high-side switch may further comprise a field effect transistor (FET), and the low-side switch may further comprise a FET.

In the example system, the high-side switch, the low-side switch, and the resonance controller may all reside within a driver integrated circuit.

### BRIEF DESCRIPTION OF THE DRAWINGS

For a detailed description of example embodiments, reference will now be made to the accompanying drawings in which:

FIG. 1 shows a block diagram of a lidar system in accordance with at least some embodiments;

FIG. 2 shows a block diagram in accordance with at least some embodiments;

FIG. 3A shows a simplified schematic of a driver circuit and laser diode in accordance with at least some embodiments;

FIG. 3B shows a simplified schematic of a driver circuit and laser diode in accordance with at least some embodiments;

FIG. 3C shows a simplified schematic of a driver circuit and laser diode in accordance with at least some embodiments;

FIG. 3D shows a simplified schematic of a driver circuit and laser diode in accordance with at least some embodiments;

FIG. 4 shows a simplified schematic of a driver circuit and laser diode in accordance with at least some embodiments;

FIG. 5 shows a timing diagram in accordance with at least some embodiments;

FIG. 6 shows a block diagram of a driver IC in accordance with at least some embodiments;

FIG. 7 shows a block diagram of a driver IC in accordance with at least some embodiments; and

FIG. 8 shows a method in accordance with at least some embodiments.

### DEFINITIONS

Various terms are used to refer to particular system components. Different companies may refer to a component by different names—this document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect or direct connection. Thus, if a first device couples to a second device, that connection may be through a direct connection or through an indirect connection via other devices and connections.

In relation to electrical devices (whether stand alone or as part of an integrated circuit), the terms “input” and “output” refer to electrical connections to the electrical devices, and shall not be read as verbs requiring action. For example, a differential amplifier (such as an operational amplifier) may have a first differential input and a second differential input, and these “inputs” define electrical connections to the operational amplifier, and shall not be read to require inputting signals to the operational amplifier.

“Assert” shall mean changing the state of a Boolean signal. Boolean signals may be asserted high or with a higher voltage, and Boolean signals may be asserted low or with a lower voltage, at the discretion of the circuit designer. Similarly, “de-assert” shall mean changing the state of the Boolean signal to a voltage level opposite the asserted state.

“Controller” shall mean, alone or in combination, individual circuit components, an application specific integrated circuit (ASIC), a microcontroller with controlling software, a digital signal processor (DSP), a processor with controlling software, a programmable logic device (PLD), or a field programmable gate array (FPGA), configured to read inputs and drive outputs responsive to the inputs.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Various embodiments are directed to resonant recharge for synchronous pulsed laser operation. More particularly, at least some example embodiments are directed to recharging a firing capacitor for a laser diode (e.g., a vertical cavity surface emitting laser (VCSEL)) by creating an oscillating voltage within inductor-capacitor (LC) circuit, and using the oscillating voltage to charge the firing capacitor. Current from the firing capacitor may be used to activate or drive the laser diode, and in some cases the activation is synchronized with the oscillating voltage. More particularly still, in example cases the oscillating voltage is a resonant voltage. During the negative half-cycle of the resonant voltage the laser diode is activated with current from the firing capacitor, and during the positive-half cycle of the resonant voltage the firing capacitor is recharged. The specification first turns to an example system to orient the reader.

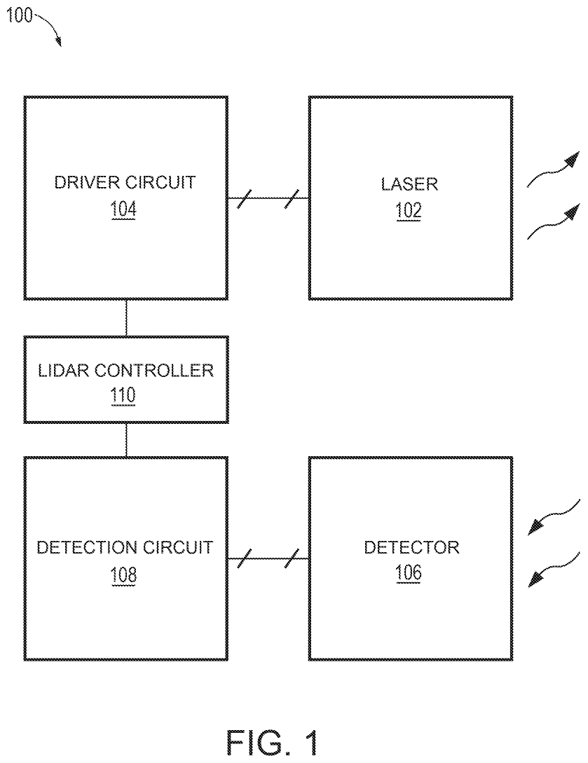

FIG. 1 shows, in block diagram form, a lidar system 100 in accordance with at least some embodiments. In particular, the example lidar system 100 comprises a laser 102, a driver circuit 104, a detector 106, a detection circuit 108, and a lidar controller 110. The laser 102 illuminates a target area (e.g., the scene in front of an automobile) with pulses of light. In some cases the laser 102 is a single laser diode, while in other cases the laser 102 is an array of laser diodes (e.g., an array of vertical-cavity surface-emitting laser (VCSEL) diodes). The light created by the laser 102 may be within the visible spectrum, or the light created may be outside the visible spectrum, such as ultraviolet or infrared light. The direction of travel or focal direction of the light created by the laser 102 may be steered in some way, such as by way of a mechanical system, an optical system, or both. In other cases, an array of laser diodes may be used, with each portion of the array focused on a particular portion of a target area.

The example laser 102 is driven by the driver circuit 104. In particular, the driver circuit 104 is coupled to the laser 102 such that the driver circuit 104, at the command of the lidar controller 110, may drive the laser 102. The command may be to drive a single pulse or single firing of the laser 102, or the command may be to create pulses of light from the laser 102. Since the example lidar system 100 is a time-of-flight type system, the driver circuit 104 may provide to the lidar controller 110 an indication of each point in time when the example laser 102 has been activated (e.g., start time). The lidar controller 110, in turn, may provide the indications to the detection circuit 108 and any other system that uses the information related to when the pulse of light was created by the laser 102.

Still referring to FIG. 1, a portion of the light launched into the target area is reflected back to the detector 106. In one example case the detector 106 is a single photo diode designed and constructed to be sensitive to the wavelength of light produced by the laser 102. In other cases, the detector 106 is an array of photo diodes. From the light detected by the detector 106, the location of objects and movement of the objects in the target area may be determined. The specification now turns to a description of the driver circuit 104 and the laser 102 in greater detail.

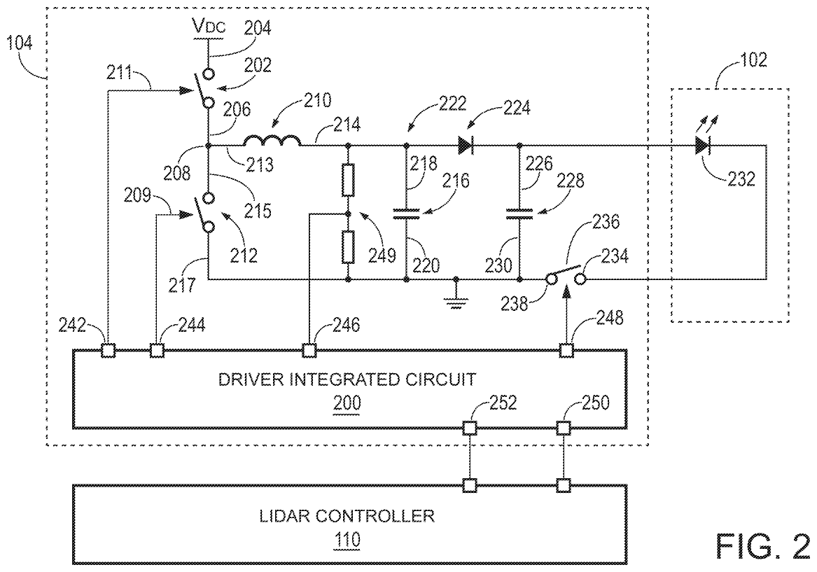

FIG. 2 shows a block diagram of an example system. In particular, FIG. 2 shows the driver circuit 104, the laser 102, and the lidar controller 110. The example driver circuit 104 comprises a driver integrated circuit (driver IC) 200 and a plurality of discrete electrical components. In particular, the example driver circuit 104 comprise a high-side switch 202. The high-side switch 202 is shown as a mechanical switch so as not to complicate the figure, but in practice the high-side switch 202 is any suitable electrically-controlled switch, such as a field effect transistor (FET). The high-side switch 202 defines a first lead 204 coupled to a power supply V_{DC} and a second lead 206 coupled to a switch node 208. The example high-side switch 202 further defines a control input 211 coupled to the driver IC 200. In situations where the high-side switch 202 is a FET, the control input 211 may be the gate of the FET. Responsive to assertion of the control input 211, the high-side switch 202 closes or becomes conductive.

The example driver circuit further comprise a low-side switch 212. The low-side switch 212 is also shown as a mechanical switch, but in practice the low-side switch 212 may be any suitable electrically-controlled switch, such as a FET. The low-side switch 212 defines a first lead 215 coupled to the switch node 208 and a second lead 217 coupled to a reference voltage (e.g., ground). The example low-side switch 212 further defines a control input 209 coupled to the driver IC 200. In situations where the low-side switch 212 is a FET, the control input 209 may be the gate of the FET. Responsive to assertion of the control input 209, the low-side switch 202 closes or becomes conductive.

The example system further comprises an inductor 210 defining a first lead 213 coupled to the switch node 208 and a second lead 214. Also present is a resonant capacitor 216 defining a first lead 218 coupled to the second lead 214 of the inductor 210, and a second lead 220 coupled to ground. The first lead 218 of the resonant capacitor 216 and the second lead 214 of the inductor define a resonant node or charge node 222.

The example driver circuit 104 further comprises a diode 224 that defines an anode coupled to the charge node 222 and a cathode. The cathode of diode 224 couples to the first lead 226 of firing capacitor 228, and the second lead 230 of the firing capacitor 228 couples to ground. The cathode of the diode 224 and the first lead 226 are coupled to the laser 102. In the example system, the laser 102 is implemented as a single laser diode 232 (e.g., a VCSEL), but as discussed above the laser 102 may be a plurality of laser diodes, possibly arranged as an array. In particular, the cathode of the diode 224 and first lead 226 couple to the anode of the laser diode 232, and the cathode of the laser diode 232 couples back into the driver circuit 104.

Still referring to FIG. 2, and in particular the driver circuit 104, the cathode of the example laser diode 232 couples to a pulse-control switch 236. In particular, the first lead 234 of the pulse-control switch 236 couples to the cathode of the laser diode 232, and the second lead 238 couples to ground. The pulse-control switch 236 is shown as a mechanical switch, but in practice the pulse-control switch 236 is any suitable electrically-controlled switch, such as a FET (e.g., gallium nitride FET). The example pulse-control switch 236 further defines a control input 240 coupled to the driver IC 200. In situations where the pulse-control switch 236 is a FET, the control input 240 may be the gate of the FET. Responsive to assertion of the control input 240, the pulse-control switch 236 closes or becomes conductive.

The example driver IC 200, which may a packaged integrated circuit device, defines a plurality of electrical pins or electrical terminals. For example, the driver IC 200 may define a high-gate terminal 242 coupled to the control input 211 of the high-side switch 202. The driver IC 200 may comprise a low-gate terminal 244 coupled to the control input 209 of the low-side switch 212. The driver IC 200 may comprise a sense terminal 246 coupled to the charge node 222. In some cases, the sense terminal 246 may couple directly the charge node 222, such as when the peak voltages at the charge node are relatively low and the driver IC 200 is designed and constructed to directly sense voltage at the charge node. However, if the peak voltage at the charge node 222 is expected to be above the breakdown voltage of the devices within the driver IC 200, the sense terminal 246 may couple to the charge node 222 through a voltage divider 249. In cases where the driver IC 200 is designed and constructed to sense voltage at the charge node 222, the voltage divider 249 may be a resistive voltage divider. In cases where the driver IC 200 is designed and constructed to sense current flow in the LC circuit, the voltage divider 249 may be a capacitive voltage divider in which the upper element is a capacitor and the lower element is a resistor.

Still referring to FIG. 2, the driver IC 200 may further comprise a pulse-gate terminal 248 coupled to the control input 240 of the pulse-control switch 236. The example driver IC 200 may further define a pulse-enable terminal 250 coupled to the lidar controller 110. By way of the lidar controller 110 and the pulse-enable terminal 250, the driver IC 200 receives commands to activate or fire the laser diode 232. However, and as will be discussed more below, the diver IC 200 only fires the laser diode 232 (e.g., makes the pulse-control switch conductive) at certain times synchronized with an oscillating voltage at the charge node 222. Finally, the example driver IC 200 defines a timing terminal 252 coupled to the lidar controller 110. In the example system, the timing terminal 252 is asserted contemporaneous with firing of the laser diode 232 so that the lidar controller 110, or other downstream devices, can make accurate time-of-flight measurements. Additional terminals would be present (e.g., power terminal, ground terminal, communication terminal), but the additional terminals are not shown so as not to further complicate the figure.

In accordance with example embodiment embodiments, the driver IC 200 controls the conductive states of the high-side switch 202 and the low-side switch 212 to induce an oscillating voltage at the charge node 222. In particular, the inductor 210 and resonant capacitor 216 form an LC circuit that has a natural resonant frequency, and by control of the high-side switch 202 and low-side switch 212 an alternating current (AC) signal is driven to the LC circuit. Responsive to the AC signal, the LC circuit may oscillate, thus creating an oscillating voltage at the charge node 222. The oscillating voltage at the charge node may be referred to as a resonance voltage.

In operation, the high-side switch 202 and the low-side switch 212 alternately couple the switch node 208 to the input voltage VDC and ground, thus creating the AC signal driven or applied to the LC circuit. It follows that the voltage at the charge node 222 will be a time-varying voltage that has a frequency. In particular, the oscillating voltage at the charge node will have a positive half-cycle and a negative half-cycle. That is, the voltage at the charge node will be positive with respect to ground for a half-cycle, and the voltage at the charge node will be negative with respect to ground for a half-cycle, and then the process repeats. In example embodiments, once the LC circuit reaches a steady state oscillation, both the resonant capacitor 216 and the firing capacitor 228 are charged during the positive half-cycle of the oscillating voltage at the charge node 222. In the case of the firing capacitor 228, the charging during the positive half-cycle is through the diode 224. During the negative half-cycle of the oscillating voltage, while the current flows from the resonant capacitor 216 and through the inductor 210 to ground, the voltage and current held on the firing capacitor 228 is isolated by the diode 224.

Responsive to assertion of the pulse-enable terminal 250 (e.g., during any phase of the oscillating voltage), during the negative half-cycle the driver IC 200 makes the pulse control switch 236 conductive, thus providing a pulse of current from the firing capacitor 228 through the laser diode 232. The specification now turns to a series of figures to explain the various phases of control of the driver circuit 104.

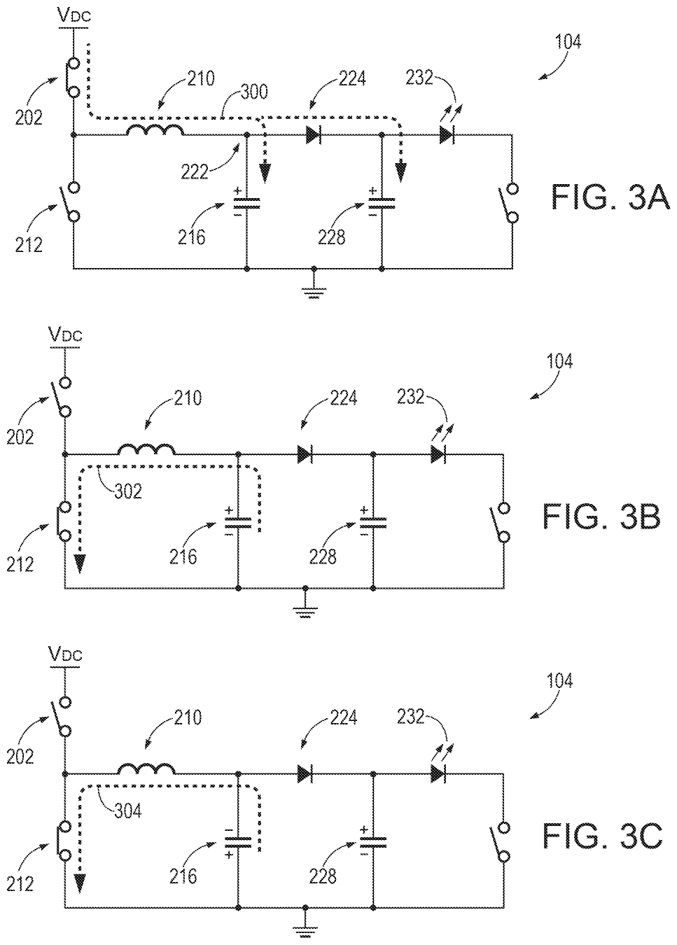

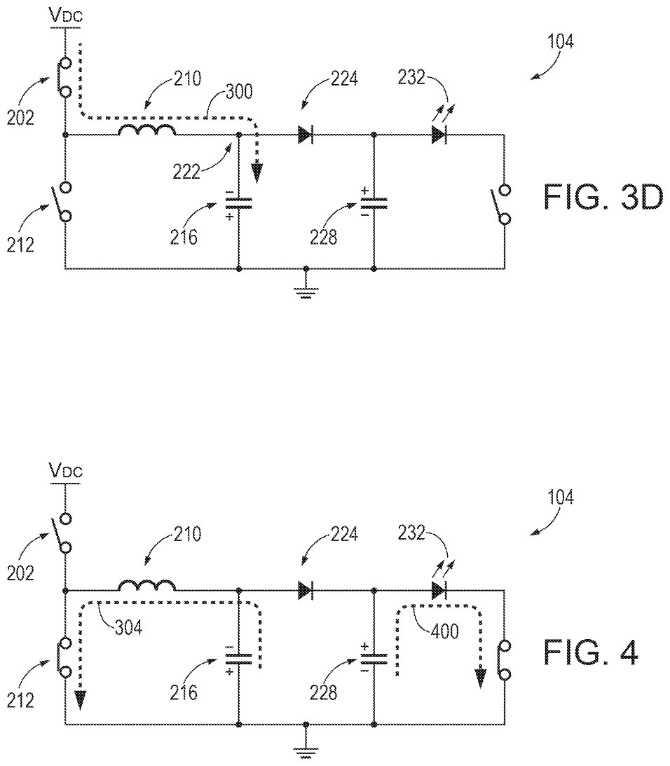

FIG. 3A shows a simplified schematic of the example driver circuit 104 and laser diode 232. Assume, for purposes of explanation, that just prior to the situation shown all the capacitances are fully discharged and the inductor carries no current. Now consider, as shown in FIG. 3A, that the high-side switch 202 is made conductive which couples the inductor 210 to the power supply V_{DC}, and the low-side switch 212 open or non-conductive. Current begins to flows from the power supply V_{DC} and through the inductor 210. However, since current cannot change through an inductor instantaneously, the current flow ramps over time. The current flow through the inductor 210 flows to the resonant capacitor 216 and to the firing capacitor 228 (through the diode 224). The example current flow is shown by line 300. Under the assumptions, the capacitors 216 and 228 are fully discharged, and thus current accumulates on the capacitors. Because voltage across a capacitor cannot change instantaneously, the voltage on the capacitors 216 and 228 (i.e., the voltage at the charge node 222) builds over time.

The current through the inductor 210 builds over time, and then as the voltage on the capacitors 216 and 228 rises, the voltage at the charge node 222 approaches the power supply V_{DC}. As the voltage at the charge node 222 approaches the power supply V_{DC} voltage, current in the inductor decreases, eventually reaching zero. The example system then enables the current to reverse flow through the inductor 210.

FIG. 3B shows a simplified schematic of the example driver circuit 104 and laser diode 232 during reverse current flow. In particular, FIG. 3B shows the high-side switch 202 non-conductive, and the low-side switch 212 conductive, thus coupling the first lead of the inductor 210 to ground. The arrangement of the high-side switch 202 and low-side switch 212 may be driven by the driver IC 200 (FIG. 2) contemporaneous with the current through the inductor 210 reaching zero during the situation of FIG. 3A. Current thus begins to flows from the resonant capacitor 216 through the inductor 210, as shown by line 302. However, since current cannot change through an inductor instantaneously, the current flow ramps over time. Moreover, because of the presence of diode 224, the firing capacitor 228 does not contribute to the reversed current flow. The current flow from the resonant capacitor 216 flows through the inductor 210 to ground. FIG. 3B shows current flow during periods of time when the voltage on the resonant capacitor 216 is positive with respect to ground. However, because of the resonant interaction between the inductor 210 and the capacitor 216, the voltage across the resonant capacitor 216 changes polarity.

FIG. 3C shows a simplified schematic of the example driver circuit 104 and laser diode 232 during the reverse current flow. In particular, in FIG. 3C the high-side switch 202 is still non-conductive, and the low-side switch 212 is still conductive. Because of the resonant interaction between the inductor 210 and the resonant capacitor 216, the voltage across the resonant capacitor 216 changes polarity as shown. Stated otherwise, in the situation of FIG. 3C the voltage at the charge node 222 is negative. Eventually, however, because of the combination of the collapsing field around the inductor 210 and the negative voltage at the charge node 222, the resonant current (shown by line 304) reaches zero.

FIG. 3D shows a simplified schematic of the example driver circuit 104 and laser diode 232. In particular, FIG. 3D shows the high-side switch 202 conductive and the low-side switch 212 non-conductive. The arrangement of the high-side switch 202 and low-side switch 212 may be driven by the driver IC 200 (FIG. 2) contemporaneous with the current through the inductor 210 reaching zero during the situation of FIG. 3C. Current thus begins to flow again from the power supply V_{DC}, through the inductor 210, and into the resonant capacitor 216, as shown by line 300. However, since the voltage across the resonant capacitor 216 was negative at the end of the situation of FIG. 3C, the voltage remains negative for a period of time as current builds through the inductor. Eventually, the voltage across the resonant capacitor 216 changes polarity again (i.e., the voltage on the charge node 222 becomes positive again), and thus the cycle returns to the situation of FIG. 3A. However, because of the voltage at the charge node 222 is initially negative in the situation of FIG. 3D, the peak current flow through the inductor 210 will be greater than for the initial case of zero volts across the resonant capacitor 216 (e.g., startup). Moreover, the increased current flow will result in a higher voltage peak at the charge node 222. That is, in certain situations the oscillating voltage at the charge node will be a resonant voltage oscillating at the resonant frequency of the LC circuit.

In the example system, the capacitance “seen” by the inductor 210 changes as a function of the half-cycle of the oscillating voltage. During a positive half cycle (and assuming the firing capacitor 228 is discharged), the total capacitance is effectively the sum of the resonant capacitor 216 and the firing capacitor 228. However, during the negative half-cycle the diode 224 blocks reverse current flow, and thus the capacitance “seen” by the inductor 210 is just the resonant capacitor 216. In accordance with example embodiments, the resonant capacitor 216 has a greater capacitance than the firing capacitor 228. In some cases, the relationship of the capacitance of the resonant capacitor to the capacitance of the firing capacitor is at least 5:1, and in a particular case 8:1. It follows that the capacitance of the firing capacitor 228 has little effect on the resonant frequency of the LC circuit. For purposes of this disclosure and the claims, resonant frequency shall encompass a range of frequencies that include the resonant frequency considering only the resonant capacitor 216, and the resonant frequency considering both the resonant capacitor 216 and the firing capacitor 228 coupled in parallel, so long as the relationship of the relationship of the capacitances is at least 5:1 in favor of the resonant capacitor 216.

FIG. 4 shows a simplified schematic of the example driver circuit 104 and laser diode 232 during firing of the laser diode 232. In particular, FIG. 4 is closely related to FIG. 3C when the high-side switch 202 is non-conductive and the low-side switch 212 is conductive. The current flow is still flowing from the resonant capacitor 216 through the inductor 210, as shown by line 304, and further the voltage on the resonant capacitor 216 has changed polarity (i.e., the charge node 222 is negative). Once the voltage on the resonant capacitor 216 changes polarity, the oscillating voltage on the charge node 222 enters the negative half-cycle. In the negative half-cycle of the oscillating voltage, the laser diode 232 can be activated with a controlled amount of energy—the energy stored in the firing capacitor 228. In particular, the laser diode 232 can be activated at any time during the negative half-cycle of the oscillating voltage because the diode 224 will remain reverse biased during the activation. More particularly still, in the example systems a pulse of current is driven, during the negative half-cycle of the oscillating voltage, from the firing capacitor 228 by making the pulse-control switch 236 conductive. Making the pulse-control switch 236 conductive creates a near instantaneous current flow (as shown by line 400) from the firing capacitor 228 through the laser diode 232. A properly designed and/or selected pulse-control switch 236, along with a properly designed and/or constructed system layout, may result in pulses of current through the laser diode 232 having a rise time below one nanosecond.

In accordance with example systems, the pulse duration is small fraction of the negative half-cycle. The firing or activation can take place at any time during the negative half-cycle of the oscillating voltage so long as the pulse is complete (i.e., the firing capacitor reaches near zero volts) before the beginning of the positive half-cycle of the oscillating voltage. During the next positive half-cycle of the oscillating voltage (e.g. FIG. 3A), the firing capacitor 228 is charged by the oscillating voltage at the charge node. Thus, the example system can sequentially activate or fire the laser diode 232 at the frequency of oscillation of the oscillating voltage on the charge node 222.

In one example system, the driver IC 200 drives the AC signal to the LC circuit at a frequency of between and including 1 megahertz (MHz) and 5 MHz, and thus the pulse frequency for the laser diode 232 may be in the same range. Stated otherwise, the inductance of the inductor 210 and the capacitance of the resonant capacitor 216 may be selected to have a resonant frequency in the range between and including 1 MHz and 5 MHz. Moreover, in one example system the peak voltage at the charge node 222 is about 200 volts, such that the peak voltage held on the firing capacitor 228 is about 200 volts by application of VDC to the switch node 208. Of course, higher and lower voltages may be used, and different frequency ranges may be used.

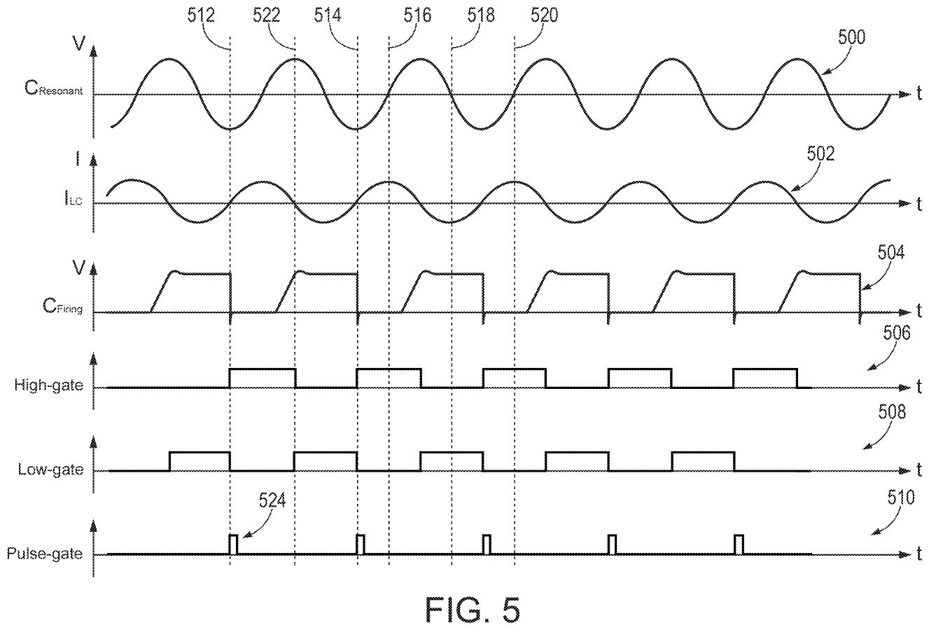

FIG. 5 shows a timing diagram in accordance with at least some embodiments. In particular, FIG. 5 shows a plurality of plots of various signals all with corresponding time, though the time aspects are not necessarily to scale. In particular, the following plots are shown: plot 500 shows voltage on the resonant capacitor 216; plot 502 shows current through the LC circuit; plot 504 shows voltage on the firing capacitor 228; plot 506 shows assertions of the high-gate terminal to drive the AC signal; plot 508 shows assertions of the low-gate terminal to drive the AC signal; and plot 510 shows assertions of the pulse-gate terminal to activate or fire the laser diode 232.

In particular, in steady state operation the voltage on the resonant capacitor 216 (plot 500), or equivalently stated the voltage on the charge node 222, is an oscillating voltage as shown. In many cases, the frequency of the oscillating voltage is set by the inductance and capacitance of the LC circuit, and the driver circuit 104 drives an AC signal to the first lead 213 of the inductor 210 to create the oscillating voltage. The oscillation voltage has a period defined between any two consecutive and corresponding features (e.g., period between vertical line 516 and 520). The period can be conceptually divided into a positive half-cycle (e.g., time between vertical lines 516 and 518) as well as a negative half-cycle (e.g., time between vertical lines 518 and 520). The oscillating voltage on the charge node 222 is related to an oscillating current (plot 502) that flows back and forth within the LC circuit. At resonance, the current makes a positive-going zero crossing contemporaneously with a minima in the oscillating voltage on the charge node 222 (e.g., at vertical line 512). Correspondingly, the current makes a negative-going zero crossing contemporaneously with a maxima in the voltage on the charge node 222 (e.g., at vertical line 522).

In order to drive or create the oscillating voltage on the charge node 222 (again, plot 500), the driver IC 200 drives the AC signal to the first lead 213 of the inductor 210 by selective control of the high-side switch 202 and the low-side switch 212. Plot 506 shows an example signal driven to the control input of the high-side switch 202 to make the high-side switch 202 conductive at appropriate times. Plot 508 shows an example signal driven to the control input of the low-side switch 212 to make the low-side switch 212 conductive at appropriate times. For example, during the period of time between vertical lines 512 and 522, the high-side switch 202 is conductive and the low-side switch is non-conductive. Thus, during this period the high-side switch 202 couples the power supply V_{DC} to the first lead 213 of the inductor 210. During the period of time between vertical lines 522 and 514, the low-side switch 212 is conductive and the high-side switch is non-conductive. Thus, during this period the low-side switch 212 couples the first lead 213 of the inductor 210 to ground. The example process repeats in each switching period. It is noted that while the example FIG. 5 shows simultaneous operations regarding the high-side switch 202 and the low-side switch 212, in practice the driver IC 200 implements a delay between making the high-side switch 202 non-conductive and making the low-side switch 212 conductive, and vice versa, to avoid shorting the power supply V_{DC} to ground through the switches 202 and 212 (sometimes referred to as shoot through).

In accordance with example embodiments, and for the reasons discussed above, the laser diode 232 may be activated or fired at any time during the negative half-cycle of the oscillating voltage. In the example timing diagram shown, the pulse-gate terminal 248 is shown to be asserted contemporaneously with each minima of the oscillating voltage on the charge node 222. For example, an asserted pulse 524 may be applied at the time represented by vertical line 512. The assertion of the pulse-gate terminal 248 thus makes the pulse-control switch 236 conductive, which applies the energy from the firing capacitor 228 through the laser diode 232. The discharge of the firing capacitor 228 thus drops the voltage on the firing capacitor 228 to zero at each firing as shown in plot 504. Parasitic inductances may make the voltage on the firing capacitor 228 ring after the current is discharged, and the ringing is shown by the slight negative voltage just after each firing. Further as shown in plot 504, the firing capacitor 228 is re-charged in each positive half-cycle of the oscillating voltage on the charge node 222.

The example timing diagram suggests one operational technique for the driver IC 200. In particular, in some embodiments of the driver IC 200 the pulse-gate terminal 248 may be asserted (thus making the pulse-control switch 236 conductive) in each switching period contemporaneously with the transition of de-asserting the high-gate terminal and asserting the low-gate terminal. For example, the driver IC 200 could simultaneously de-assert the high-gate terminal 242 and assert the pulse-gate terminal 248. In other cases, the driver IC 200 could assert the pulse-gate terminal 248 in the lag time between de-assertion of the high-gate terminal 242 and assertion of the low-gate terminal 244. In yet still other cases, the driver IC 200 could simultaneously assert the low-gate terminal 244 and assert the pulse-gate terminal 248. Inasmuch as the activation or firing of the laser diode 232 may take place any time during the negative half-cycle, other operational techniques, discussed more below, may be used. The specification now turns example driver ICs 200.

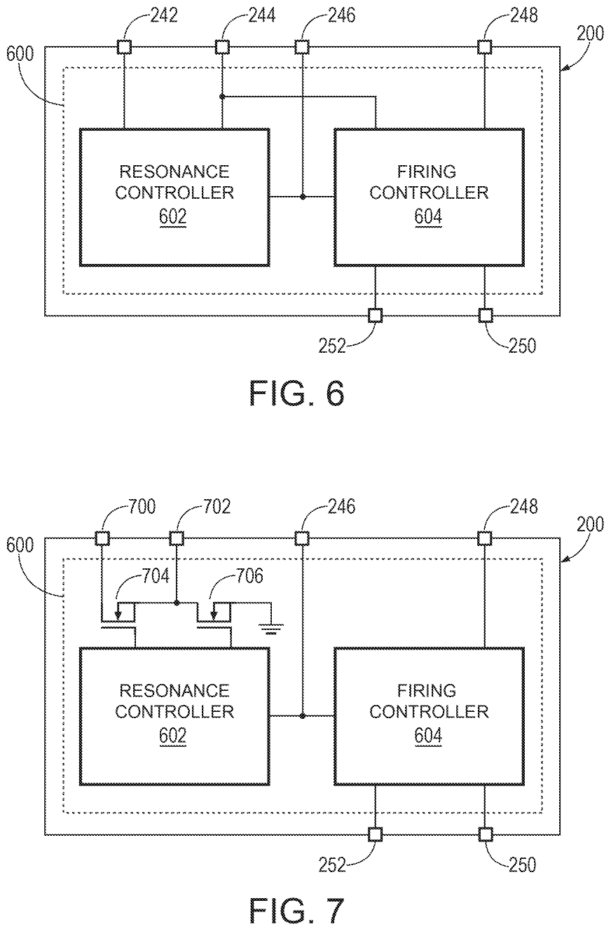

FIG. 6 shows a block diagram of an example driver IC 200. In particular, FIG. 6 shows the driver IC 200 may comprise one or more substrates of semiconductor material (e.g., silicon), such as substrate 600, encapsulated within the packaging. Bond pads or other connection points of the substrate 600 couple to electrical terminals of the driver IC 200. The example driver IC 200 defines the high-gate terminal 242, the low-gate terminal 244, the sense terminal 246, the pulse-gate terminal 248, the pulse-enable terminal 250, and the timing terminal 252. Additional terminals would be present (e.g., power terminal, ground terminal), but the additional terminals are not shown so as not to further complicate the figure.

Within the driver IC 200, and in particular on the substrate 600, resides an example resonance controller 602 and firing controller 604. The example resonance controller 602 couples to the high-gate terminal 242 and the low-gate terminal 244. The resonance controller 602 is designed and constructed to control the asserted states of the high-gate terminal 242 and the low-gate terminal 244, and thus to control the conductive states of the high-side switch 202 and the low-side switch 212, respectively. For example, the resonance controller 602 may be designed and constructed to, during operation, assert the high-gate terminal 242 for a first duration within a switching period while holding the low-gate terminal 244 de-asserted, and configured to assert the low-gate terminal 244 for a second duration within the switching period while holding the high-gate terminal 242 de-asserted. Thus, the resonance controller 602 may drive the AC signal to the first lead 218 of the inductor 210 to create the oscillating voltage on the charge node 222.

In some cases, the resonance controller 602 drives the terminals in an open loop sense. That is, once powered-on and operational, the resonance controller 602 drives the alternating asserted signals without regard to the actual voltage and/or current at the charge node 222. For example, the circuit designer may select a resonant frequency based on the inductance and capacitance of the LC circuit, and the resonant frequency may be conveyed to the resonance controller 602 in some form, such as by the resistance values of external resistors (not shown) coupled to the driver IC 200, or by serial communication to the resonance controller 602 through a communication terminal (again not shown).

Still referring to FIG. 6. The example firing controller 604 is coupled to the pulse-gate terminal 248, the pulse-enable terminal 250, and the timing terminal 252. In some cases, the firing controller 604 is coupled to the low-gate terminal 244. In accordance with example embodiments, the firing controller 604 is designed and constructed to assert the pulse-gate terminal 248 only during the negative half-cycle of the oscillating voltage. In one example case, the firing controller 604 asserts the pulse-gate terminal 248 contemporaneously with each de-assertion of the low-gate terminal 244. Alternatively, and though not specifically shown, the firing controller 604 may couple to the high-gate terminal 242, and may assert the pulse-gate terminal 248 on each assertion of the high-gate terminal 242.

In yet still other cases, the firing controller 604 couples to the sense terminal 246, and may assert the pulse-gate terminal 248 based on an attribute of oscillation sensed by way of the sense terminal 246. In one example case, the attribute of oscillation may be the voltage on the charge node 222 as sensed at the sense terminal 246. By monitoring an attribute of the sensed voltage (e.g., polarity, zero crossings, maxima timing, minima timing), the firing controller 604 may determine timing of the negative half-cycle of the oscillating voltage on the charge node 222, and assert the pulse-gate terminal 248 during the negative half-cycle. In another example, the attribute of oscillation may be current flow through the LC circuit as sensed at the sense terminal 246 (e.g., a voltage indicative of current). By monitoring an attribute of the sensed voltage indicative of current (e.g., maxima timing, minima timing), the firing controller 604 may determine timing of the negative half-cycle of the oscillating voltage on the charge node 222, and assert the pulse-gate terminal 248 during the negative half-cycle.

In some cases the firing controller 604 asserts the pulse-gate terminal 248 in each negative half-cycle of the oscillating voltage at the charge node 222 (independent of how the negative half-cycle is determined). In other cases, however, the firing controller 604 may only assert the pulse gate terminal 248 responsive to a signal from another device (e.g., the lidar controller 110). Thus, in some cases the firing controller 604 asserts the pulse-gate terminal 248 in a negative half-cycle only if a pulse-enable signal on the pulse-enable terminal 250 is asserted. Assertion of the pulse-enable terminal 250 may occur asynchronously with the negative half-cycles of the oscillating voltage at the charge node 222, and thus the firing controller 604 does not necessarily assert the pulse-gate terminal 248 directly responsive to assertion of the pulse-enable terminal 250. Rather, the firing controller 604 may: assert the pulse-gate terminal 248 in the currently existing negative half-cycle if the pulse-enable terminal 250 is asserted within the currently existing negative half-cycle; or assert the pulse-gate terminal 248 in a subsequent negative half-cycle (e.g., an immediately subsequent negative half-cycle) if the pulse-enable terminal 250 is asserted in a positive half-cycle.

Finally, the example firing controller 604 may provide timing signals for downstream components (e.g., the lidar controller 110 or the detection circuit 108) such that time-of-flight calculations can be made. In particular, in example cases the firing controller 604 may assert the timing terminal 252 simultaneously with each assertion of the pulse-gate terminal 248 such that the downstream components may make the time-of-flight calculations.

Returning briefly to FIG. 2. In the various embodiments discussed to this point the high-side switch 202 and the low-side switch 212 are shown to be discrete components separate and apart from the driver IC 200. However, in other cases the driver IC 200 may include the high-side switch 202 and the low-side switch 212 within the driver IC 200 for convenience of the circuit designer, and possibly to reduce the pin count of the driver IC 200.

FIG. 7 shows a block diagram of a driver IC 200 in accordance with alternative embodiments. In particular, FIG. 7 shows that the driver IC 200 again may comprise one or more substrates of semiconductor material (e.g., silicon), such as substrate 600, encapsulated within the packaging. The example driver IC 200 of FIG. 7 defines a source terminal 700, a switch-node terminal 702, as well as the remaining terminals discussed with respect to FIG. 6. In the example driver IC 200 of FIG. 7, the high-side switch and the low-side switch are implemented within the driver IC 200 as high-side FET 704 and low-side FET 706. In FIG. 7 the FETs are shown to be constructed on the substrate 600; however, in other cases the FETs may be separately constructed and packaged together in the driver IC 200 (e.g., a multi-chip module).

The high-side FET 704 defines a drain coupled to the source terminal 700 and a source coupled to the switch-node terminal 702. In practice, the power supply V_{DC} is coupled directly to the source terminal 700, and the switch-node terminal 702 is coupled to the first lead 215 of the inductor 210. The gate of the high-side FET 704 is coupled to the resonance controller 602. The low-side FET 706 defines a drain coupled to the switch-node terminal 702 and a source coupled to ground. The gate of the low-side FET 706 is coupled to the resonance controller 602.

Operation of the driver IC 200 of FIG. 7 is conceptually the same as discussed with respect to FIG. 6; however, when the high-side FET 704 needs to be conductive the gate of the high-side FET 704 is asserted by the resonance controller 602. Similarly, when the low-side FET 706 needs to be conductive the gate of the low-side FET 706 is asserted by the resonance controller 602. Thus, the entire operational description regarding the resonance controller 602 is not repeated again here so as not to unduly lengthen the specification. Similarly, the firing controller 604 of FIG. 7 works the same as discussed with respect to FIG. 6 and the prior discussion, and thus entire operational description regarding the firing controller 604 is not repeated again here so as not to unduly lengthen the specification.

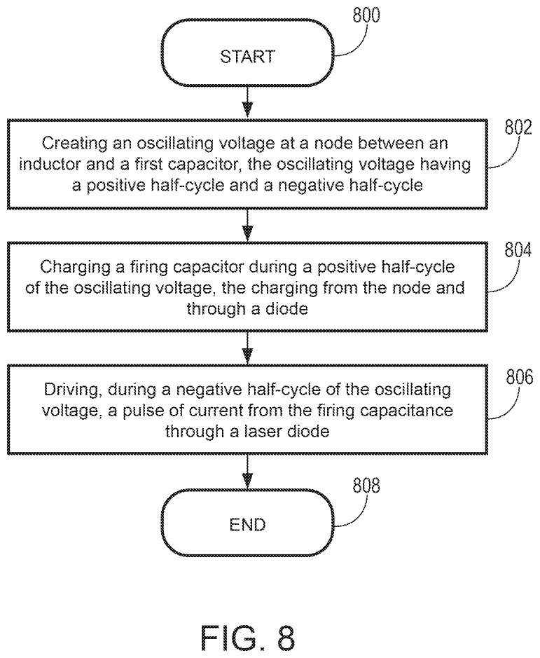

FIG. 8 shows a method of activating a laser diode in accordance with at least some embodiments. In particular, the method starts (block 800) and comprises: creating an oscillating voltage at a node between an inductor and a first capacitor, the oscillating voltage having a positive half-cycle and a negative half-cycle (block 802); charging a firing capacitor during a positive half-cycle of the oscillating voltage, the charging from the node and through a diode (block 804); and driving, during a negative half-cycle of the oscillating voltage, a pulse of current from the firing capacitance through a laser diode (block 806). Thereafter the method ends (block 808), likely to be restated on the next activation of the laser diode.

Many of the electrical connections in the drawings are shown as direct couplings having no intervening devices, but not expressly stated as such in the description above. Nevertheless, this paragraph shall serve as antecedent basis in the claims for referencing any electrical connection as “directly coupled” for electrical connections shown in the drawing with no intervening device(s).

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A method of activating a laser diode, the method comprising:
creating an oscillating voltage at a node between an inductor and a first capacitor, the oscillating voltage having a positive half-cycle and a negative half-cycle;
charging a firing capacitor during the positive half-cycle of the oscillating voltage, the charging from the node and through a diode; and
driving, during the negative half-cycle of the oscillating voltage, a pulse of current from the firing capacitor through the laser diode.

2. The method of claim 1 wherein creating the oscillating voltage at the node further comprises:
a) coupling a first lead of the inductor to a power source; and then
b) coupling the first lead of the inductor to ground; and
c) repeating steps a) and b) at a resonant frequency.

3. The method of claim 1 wherein charging the firing capacitor further comprises charging the firing capacitor in parallel with charging the first capacitor during the positive half-cycle of the oscillating voltage.

4. The method of claim 1 wherein driving the pulse of current from the firing capacitor further comprises discharging the firing capacitor through the laser diode and an electrically-controlled switch.

5. A driver integrated circuit for controlling activation of a laser diode, the driver integrated circuit comprising:
a high-gate terminal, a low-gate terminal, a sense terminal, and a pulse-gate terminal;
a resonance controller coupled to the high-gate terminal and the low-gate terminal, the resonance controller configured to assert the high-gate terminal for a first duration within a switching period, and configured to assert the low-gate terminal for a second duration within the switching period; and
a firing controller coupled to the sense terminal and the pulse-gate terminal, the resonance controller configured to assert the pulse-gate terminal based on a signal sensed by way of the sense terminal.

6. The driver integrated circuit of claim 5 further comprising:
a pulse-enable terminal;
the firing controller coupled to the pulse-enable terminal, and the firing controller further configured to assert the pulse-gate terminal when the pulse-enable terminal is asserted.

7. The driver integrated circuit of claim 5 further comprising:
the signal sensed by way of the sense terminal is a signal indicative of voltage at a charge node; and
wherein the firing controller asserts the pulse-gate terminal only when the signal indicative of voltage indicates a voltage on the charge node is negative.

8. The driver integrated circuit of claim 5 further comprising:
the signal sensed by way of the sense terminal is a signal indicative of current flow in an inductor-capacitor circuit; and
wherein the firing controller asserts the pulse-gate terminal only when the signal indicative of current flow indicates a voltage on a charge node is negative.

9. The driver integrated circuit of claim 5 further comprising:
the resonance controller coupled to the sense terminal, and the resonance controller further configured to:
measure an attribute of oscillation on the by way of the sense terminal; and
control frequency of assertion of the high-gate terminal based on the attribute of oscillation.

10. A driver integrated circuit for controlling activation of a laser diode, the driver integrated circuit comprising:
a source terminal, a switch-node terminal, a sense terminal, a ground terminal, and a pulse-gate terminal;
a high-side field-effect transistor (high-side FET) defining a drain coupled to the source terminal, a source coupled to the switch-node terminal, and a gate;
a low-side FET defining a drain coupled to the switch-node terminal, a source coupled to the ground terminal, and a gate;
a resonance controller coupled to the gate of the high-side FET and the gate of the low-side FET, the resonance controller configured to assert the gate of the high-side FET for a first duration within a switching period, and configured to assert the gate of the low-side FET during a second duration within the switching period; and
a firing controller coupled to the sense terminal and the pulse-gate terminal, the firing controller configured to sense an attribute of oscillation through the sense terminal, and assert the pulse-gate terminal based on the attribute of oscillation.

11. The driver integrated circuit of claim 10 further comprising:
a pulse-enable terminal;
the firing controller coupled to the pulse-enable terminal, and the firing controller further configured to assert the pulse-gate terminal only when the pulse-enable terminal is asserted.

12. The driver integrated circuit of claim 10 further comprising:
the attribute of oscillation is a signal indicative of voltage at a charge node; and
wherein the firing controller asserts the pulse-gate terminal only when the signal indicative of voltage indicates a voltage on the charge node is negative.

13. The driver integrated circuit of claim 10 further comprising:
the attribute of oscillation is a signal indicative of current flow in an inductor-capacitor (LC) circuit; and
wherein the firing controller asserts the pulse-gate terminal only when the signal indicative of current flow indicates a voltage on a charge node is negative.

14. The driver integrated circuit of claim 10 further comprising:
the resonance controller coupled to the sense terminal, and the resonance controller further configured to:
sense the attribute of oscillation by way of the sense terminal; and
control frequency of assertion of the gate of the high-side FET based on the attribute of oscillation.

15. A system for light detecting and ranging, comprising:
an inductor-capacitor circuit (LC circuit) defining a first lead, a second lead, and a charge node between an inductor and a capacitor;
a high-side switch defining a first lead coupled to a power supply, a second lead coupled to the first lead of the LC circuit, and a control input;
a low-side switch defining a first lead coupled to the first lead of the LC circuit, a second lead coupled to the ground, and a control input;
a diode defining an anode coupled to the charge node, and a cathode;
a firing capacitor defining a first lead coupled to the cathode of the diode, and a second lead coupled to the to the ground;
a laser diode;
a pulse-control switch coupled to the firing capacitor and the laser diode, the pulse-control switch configured to couple the firing capacitor to the laser diode based on a control input;
a resonance controller coupled to the control inputs of the high-side switch, the low-side switch, and the pulse-control switch, the resonance controller configured to:
create an oscillating voltage at the charge node by control of the high-side switch and the low-side switch, the oscillating voltage having a frequency, a positive half-cycle, and a negative half-cycle; and
generate a laser pulse from the laser diode during the negative half-cycle of the oscillating voltage by making the pulse-control switch conductive.

16. The system of claim 15 wherein when the resonance controller creates the oscillating voltage at the charge node, the resonance controller is further configured to:
a) assert the control input of the high-side switch to couple the first lead of the LC circuit to a power source; and then
b) assert the control input of the low-side switch to couple the first lead of the LC circuit to ground; and
c) repeat steps a) and b) at the frequency.

17. The system of claim 15 further comprising a firing controller defining a pulse-enable input, the firing controller configured to assert the control input of the pulse-control switch only during the negative half-cycle of the oscillating voltage when the pulse-enable input is asserted.

18. The system of claim 15 further comprising:
a current sensor associated with the charge node; and
the resonance controller coupled to the current sensor, and the resonance controller further configured to:
measure values indicative of current by way of the current sensor; and
control the frequency of the oscillating voltage based on the values indicative of current.

19. The system of claim 15:
wherein the high-side switch further comprises a field effect transistor (FET);
wherein the low-side switch further comprises a FET.

20. The system of claim 15 wherein the high-side switch, the low-side switch, and the resonance controller all reside within a driver integrated circuit.
